(19) United States
(12) Patent Application Publication
(10) Pub. No.: US 2026/0353560 A1
(43) Pub. Date: Nov. 5, 2026

(54) chip packaging structure and MANUFACTURING METHOD THEREOF

(71) Applicant: SJ Semiconductor(Jiangyin) Corporation, Jiangyin (CN)

(72) Inventors: Yenheng CHEN, Jiangyin (CN); Chengchung LIN, Jiangyin (CN); Jin YANG, Jiangyin (CN)

(73) Assignee: SJ Semiconductor(Jiangyin) Corporation, Jiangyin, JS (CN)

(21) Appl. No.: 19/111,804

(22) PCT Filed: Jun. 9, 2023
(86) PCT No.: PCT/CN2023/099291

§ 371 Date: Mar. 14, 2025

(30) Foreign Application Priority Data
Sep. 20, 2022 (CN) 202211145294.8

(51) Int. Cl. H05K 1/14; H05K 1/181; H05K 3/36

(52) U.S. Cl. CPC H05K 1/141; H05K 1/181; H05K 3/368; H05K 2201/049; H05K 2201/10522

(57) ABSTRACT

A chip packaging structure and a manufacturing method thereof are disclosed. The method replaces an expensive organic substrate in related technologies with a composite structure of a rewiring layer and a prepreg substrate; the rewiring layer is used to realize fine-pitch wiring in a high-density circuit, and then is bonded to the prepreg substrate to achieve coarser wiring connections. This composite structure has significant cost advantages over organic substrates and can be applied to chip products that do not require high frequency or low latency. In addition, simultaneously bonding of multiple die stacks formed by dies and the rewiring layer to the surface of the prepreg substrate avoids the low manufacturing efficiency of bonding each die individually, effectively reducing production costs and improving manufacturing efficiency.

### FIELD OF THE INVENTION

The present disclosure relates to semiconductor packaging, and in particular, to a chip packaging structure and a manufacturing method thereof.

### BACKGROUND OF THE INVENTION

In recent years, flip-chip packaging has emerged as the mainstream electronic packaging solution, accounting for 60% to 70% of the entire integrated circuit packaging market. For high-end flip-chip packaging structures, such as Central Processing Units (CPUs) used in computer servers, Artificial Intelligence (AI) applications, and High-Performance Computing (HPC), often multiple dies need to be integrated on one single organic substrate. This type of chip packaging structure typically includes multiple dies such as core dies, input/output (IO) dies, cache or Static Random-Access Memory (SRAM) dies, and fabric dies. As shown in FIG. 1, in a typical flip-chip package, one or more dies 101 are directly bonded to a single organic substrate 100 to form a flip-chip package, which usually requires fine-pitch wiring. This demands very fine line/space (L/S) dimensions, such as 15/15 μm or even below 10/10 μm, necessitating the use of a high-density interconnected (HDI) organic substrate 100 to achieve signal transmission. HDI organic substrates typically include dielectric insulating layers made of Ajinomoto Build-up Film (ABF), signal layers, ground (GND) layers, and power layers made of copper. For high-performance products, organic substrates often have 8+2+8 layers, can also go even 12+2+12 layers or more, which utilizes advanced materials and complex manufacturing processes. Such HDI organic substrates can result in a very high cost. When multiple dies are directly bonded to an organic substrate, thermo-compression bonding (TCB) is typically used to bond each die separately to the substrate, which leads to low manufacturing efficiency.

Especially for certain low-end computer servers or workstations, the requirements for chip's electronic frequency or signal latency are not as strict as the high-end chips, making the use of such expensive HDI organic substrates unnecessary. Therefore, there is a need to propose a new packaging structure to replace these costly organic substrates.

### SUMMARY OF THE INVENTION

In view of the above-mentioned shortcomings of related technologies, the present disclosure provides a chip packaging structure and a method for preparing the same for solving the problems of using expensive organic substrates and facing low manufacturing efficiency in related technologies.

The disclosed method for preparing a chip packaging structure includes:
S1: sequentially forming a rewiring layer and dies on a carrier plate;
S2: removing the carrier plate, dividing the rewiring layer along gaps between adjacent dies to form die stacks, wherein each of the die stacks includes one of the dies and a corresponding segment of the rewiring layer vertically connected to said die; and
S3: simultaneously bonding the die stacks to a surface of a prepreg substrate, wherein the prepreg substrate includes two or more layers of conductive boards and prepreg layers, wherein each of the prepreg layers is sandwiched between two adjacent ones of the conductive boards.

Preferably, the conductive boards are PCBs each including a core board and a metal layer on a surface of the core board.

Preferably, the prepreg layers are made of impregnated resin.

Preferably, a total number of the conductive boards and the prepreg layers in the prepreg substrate is at least ten.

Preferably, the rewiring layer includes a dielectric layer and a metal wiring layer within the dielectric layer.

The chip packaging structure includes:
a prepreg substrate, wherein the prepreg substrate includes two or more layers of conductive boards and prepreg layers, wherein each of the prepreg layers is sandwiched between two adjacent ones of the conductive boards;
die stacks, disposed on the prepreg substrate, wherein each of the die stacks includes one of dies and a corresponding segment of a rewiring layer vertically connected to said die

Preferably, the conductive boards are PCBs each including a core board and a metal layer on a surface of the core board.

Preferably, the prepreg layers are made of impregnated resin.

Preferably, a total number of the conductive boards and the prepreg layers in the prepreg substrate is at least ten.

Preferably, the rewiring layer includes a dielectric layer and a metal wiring layer within the dielectric layer.

As described above, the present disclosure provides a chip packaging structure and a method for preparing the same; the method replaces an expensive organic substrate in related technologies with a composite structure including a rewiring layer and a prepreg substrate; the rewiring layer helps to realize fine-pitch wiring, and then the prepreg substrate is bonded to the rewiring layer to achieve less dense wiring connections. This composite structure has significant cost advantages over organic substrates and can be applied to chip products that do not require high frequency or low latency. In addition, simultaneously bonding of multiple die stacks formed by dies and the rewiring layer to the surface of the prepreg substrate avoids the low manufacturing efficiency of bonding each die individually, effectively reducing production costs and improving manufacturing efficiency.

### BRIEF DESCRIPTION OF DRAWINGS

FIG. 1 is a schematic structural diagram of an organic substrate in related technologies.

FIG. 2 is a schematic structural diagram of two separate die stacks having one rewiring layer and one chip each before they are formed on a carrier plate according to an embodiment of the present disclosure.

FIG. 3 is a schematic structural diagram of die stacks after they are formed on a carrier plate according to an embodiment of the present disclosure.

FIG. 4 is a side view of a chip packaging structure according to an embodiment of the present disclosure.

FIG. 5 is a side view of a conductive board according to an embodiment of the present disclosure.

FIG. 6 is a top view of a chip packaging structure according to an embodiment of the present disclosure.

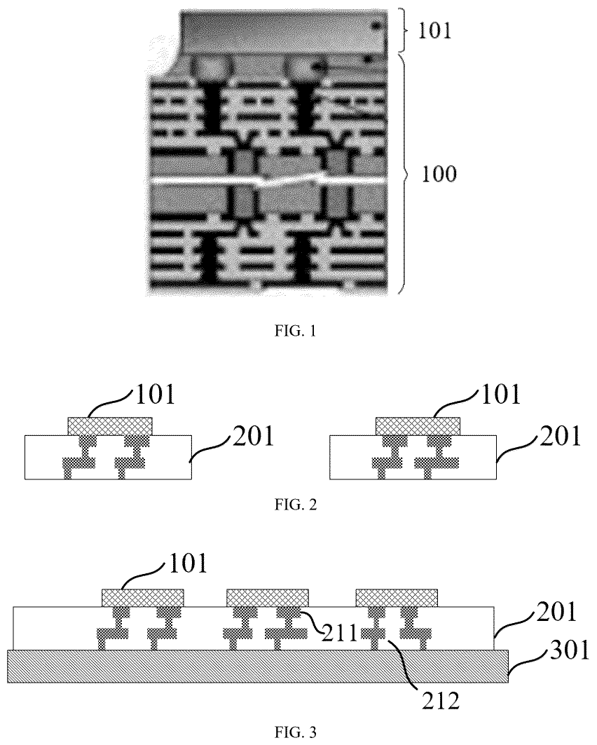

### REFERENCE NUMERALS

101 Die
201 Rewiring Layer
211 Metal Wiring Layer
212 Dielectric Layer
301 Carrier plate
401 Prepreg Substrate
410 Conductive Board
420 Prepreg Layer
411 Metal Layer
412 Core Board
413 Metal Layer

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should include the length, width, and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers. Herein, “between . . . ” are used to include both endpoints.

In the context of this disclosure, a structure described with a first feature “on top” of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

In view of the drawback of expensive HDI organic substrates in related technologies, the present disclosure uses prepreg substrates (soaked substrates before mounting process) instead. Silicon dies or chips (hereinafter, dies) are first attached to a substrate made using a fan-out RDL (redistribution layer) process for fine pitch wiring. Then, using standard flip-chip assembly techniques, the assembled substrate with additional dies is connected to a low-cost prepreg substrate with a multilayer structure for coarse electrical wiring. This stacked packaging structure, formed using such a packaging method, is primarily targeted at applications that do not require the highest frequency or the lowest latency.

### Embodiment 1

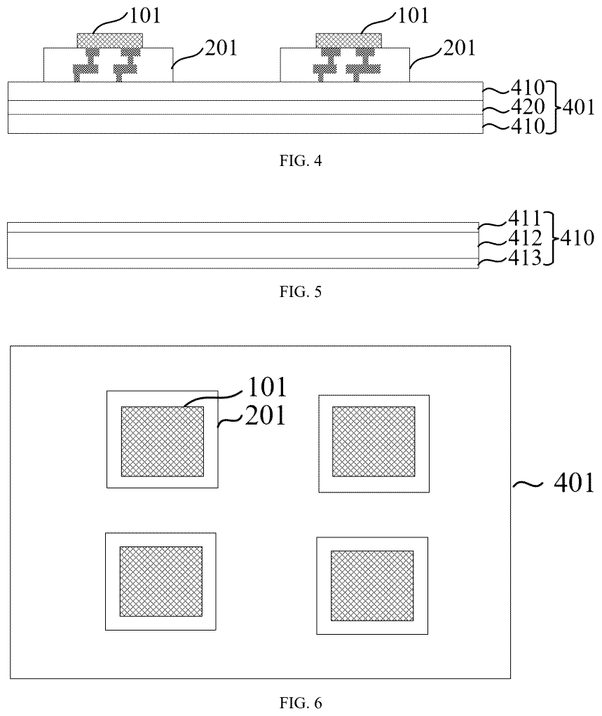

As shown in FIG. 2 to FIG. 6, Embodiment 1 provides a method for preparing a chip packaging structure, and the method includes steps S1 to S3.
S1: sequentially forming a rewiring layer 201 and dies 101 on a carrier plate 301, as shown in FIGS. 2 and 3;
S2: removing the carrier plate 301, scribing the rewiring layer 201 along gaps between adjacent dies 101 to form die stacks, wherein each of the die stacks includes one of the dies 101 and a corresponding segment of the rewiring layer 201 vertically connected to said die 101, as shown in FIG. 4;
S3: simultaneously bonding the die stacks to a surface of a prepreg substrate 401, wherein the prepreg substrate 401 includes two or more layers of conductive boards 410 and prepreg layers 420, wherein each of the prepreg layers 420 is sandwiched between two adjacent ones of the conductive boards 410, as shown in FIGS. 4 and 5.

Specifically, as shown in FIG. 5, the conductive board 410 may be a PCB board, each of which typically includes a core board 412 and at least one metal layer 411 disposed on a surface of the core board 412, wherein a material of the metal layer 411 is typically copper. The core board 412 is a rigid sheet with a predetermined thickness; it may be made of fiberglass to ensure that the PCB board has enough rigidity. Each PCBs may be a single-sided PCB or a double-sided PCB; that is, the metal layer(s) may be located on one or two surfaces of the core board 412. As an example, the conductive boards 410 in FIG. 5 are double-sided PCBs with metal layers 411, 413 on upper and lower surfaces of the core board 412, respectively.

A prepreg layer 420 is also known as a semi-cured sheet or pre-impregnated sheet, and is made of impregnated resin as an example. Impregnated resin is obtained using cross-linked copolymers as carriers resin, which is then impregnated in a liquid extractant to absorb various liquid ion exchangers. In the production of reinforced composite materials, various skeleton materials (such as wood, fabric, carbon fiber, or glass fiber, including resins like epoxy and phenolic resin) may be impregnated. As an example, each prepreg layer 420 is used as bonding materials between corresponding conductive boards 410 and for interlayer insulation. During lamination, resin of each prepreg layer 420 melts, flows, and solidifies, bonding layers of the circuit together and forming a reliable insulating layer. As an example, a specific structure with two layers of conductive boards is illustrated in FIG. 4. In practice, the number of conductive boards can be adjusted as needed as long as each two conductive boards are sandwiched with a prepreg layer 420. For example, the total number of alternating conductive boards 410 and the prepreg layers 420 in the prepreg substrate 401 may be ten or more.

A large-scale reflow soldering process may be used in step S3 to simultaneously bond the multiple die stacks to the surface of the prepreg substrate 401 in a parallel manner, which can effectively save preparing costs and improve production efficiency as compared to existing techniques where dies are bonded one by one to an organic substrate by means of TCB.

Specifically, the carrier plate 301 includes one of a glass substrate, a metal substrate, a semiconductor substrate, a polymer substrate, and a ceramic substrate. As an example, the carrier plate 301 is a glass substrate, which is less costly, and it is easy to form a temporary bonding adhesive (TB adhesive) on a surface of the glass substrate to bond the rewiring layer 201. Additionally, using the glass substrate can reduce the difficulty of subsequently peeling off the carrier plate 301. When peeling off is required, the TB adhesive can be heated using a laser to make it less sticky to separate the rewiring layer 201 and the carrier plate 301 from each other.

Specifically, the rewiring layer 201 includes a dielectric layer 212 and a metal wiring layer 211 disposed within the dielectric layer 212. The dielectric layer 212 is made of one or more of epoxy, silicone, Polyimide (PI), Polybenzoxazole (PBO), Benzocyclobutene (BCB), silicon oxide, phosphor-silicon glass, and fluorine-containing glass; The metal wiring layer 211 is made of one or more of copper, aluminum, nickel, gold, silver, and titanium. The materials, number of layers and distribution morphology of the dielectric layer 212 and the metal wiring layer 211 may be set according to specific conditions of the semiconductor chip; preferably, there are 4 or 5 layers of dielectric layers 212 and corresponding metal wiring layers 211. The dies 101 may be one or more of core dies, IO dies, cache or SRAM dies, and fabric dies.

The method of the present disclosure replaces an expensive organic substrate 100 in related technologies with a composite structure of a rewiring layer 201 and a prepreg substrate 401; the rewiring layer 201 is used to realize fine-pitch wiring, and then bonded to the prepreg substrate 401 to achieve coarser wiring connections. This composite structure has significant cost advantages over organic substrates and can be applied to chip products that do not require high frequency or low latency. In addition, simultaneously bonding of multiple die stacks to the surface of a prepreg substrate avoids the low manufacturing efficiency of bonding each die individually, effectively improving production capacity.

### Embodiment 2

Embodiment 2 provides a chip packaging structure, as shown in FIG. 4 to FIG. 6, which may be produced by the method described in Embodiment 1 or any other applicable preparation methods. The chip packaging structure specifically includes:
a prepreg substrate 401, wherein the prepreg substrate 401 includes two or more layers of conductive boards 410 and prepreg layers 420, wherein each of the prepreg layers 420 is sandwiched between two of the conductive boards 410; and
die stacks, disposed on the prepreg substrate 401, wherein each of the die stacks includes one of dies 101 and a corresponding segment of a rewiring layer 201 vertically connected to said die 101.

Specifically, as shown in FIGS. 4 and 5, the conductive board 410 may be a PCB, it typically includes a core board 412 and at least one metal layer 411 disposed on a surface of the core board 412, wherein a material of the metal layer 411 is typically copper. The core board 412 is a rigid sheet with a certain thickness; it may be made of fiberglass to ensure that the PCB board has enough rigidity. Each PCB may be a single-sided PCB or a double-sided PCB; that is, the metal layer(s) may be located on one or two surfaces of the core board 412. As an example, the conductive boards 410 in FIG. 4 are double-sided PCBs with metal layers 411, 413 on both upper and lower surfaces of the core board 412, respectively.

A prepreg layer 420 is also known as a semi-cured sheet or Pre-impregnated sheet, and is made of impregnated resin as an example. Impregnated resin is obtained using cross-linked copolymers as carriers resin, which is then impregnated in a liquid extractant to absorb various liquid ion exchangers. In the production of reinforced composite materials, various skeleton materials (such as wood, fabric, carbon fiber, or glass fiber, including resins like epoxy and phenolic resin) may be impregnated. As an example, each prepreg layer 420 is used as bonding materials between corresponding conductive boards 410 and for interlayer insulation. During lamination, resin of each prepreg layer 420 melts, flows, and solidifies, bonding layers of the circuit together and forming a reliable insulating layer. As an example, a specific structure with two layers of conductive boards is illustrated in FIG. 4. In practice, the number of conductive boards can be adjusted as needed as long as each two adjacent conductive boards are connected by a prepreg layer 420. For example, the total number of the conductive boards 410 and the prepreg layers 420 in the prepreg substrate 401 may be ten or more.

Specifically, the rewiring layer 201 includes a dielectric layer 212 and a metal wiring layer 211 disposed within the dielectric layer 212. The dielectric layer 212 is made of one or more of epoxy, silicone, PI, PBO, BCB, silicon oxide, phosphor-silicon glass, and fluorine-containing glass; The metal wiring layer 211 is made of one or more of copper, aluminum, nickel, gold, silver, and titanium. The materials, number of layers and distribution morphology of the dielectric layer 212 and the metal wiring layer 211 may be set according to specific conditions of the semiconductor chip; preferably, there are 4 or 5 layers of dielectric layers 212 and corresponding metal wiring layers 211. The dies 101 may be one or more of core dies, IO dies, cache or SRAM dies, and fabric dies.

As described above, the present disclosure provides a chip packaging structure and a method for preparing the same; the method replaces an expensive organic substrate in related technologies with a composite structure of a rewiring layer and a prepreg substrate; the rewiring layer is used to realize fine-pitch wiring, and then bonded to the prepreg substrate to achieve coarser wiring connections. This composite structure has significant cost advantages over organic substrates and can be applied to chip products that do not require high frequency or low latency. Additionally, simultaneously bonding of multiple die stacks formed by dies and the rewiring layer to the surface of the prepreg substrate avoids the low manufacturing efficiency of bonding each die individually, effectively reducing production costs and improving manufacturing efficiency

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A method for preparing a chip packaging structure, comprising:
S1: sequentially forming a rewiring layer and dies on a carrier plate;
S2: removing the carrier plate, dividing the rewiring layer along gaps between adjacent dies to form die stacks, wherein each of the die stacks comprises one of the dies and a corresponding segment of the rewiring layer vertically connected to the die; and
S3: simultaneously bonding the die stacks to a surface of a prepreg substrate, wherein the prepreg substrate comprises two or more layers of conductive boards and prepreg layers, wherein each of the prepreg layers is sandwiched between two of the conductive boards.

2. The method according to claim 1, wherein the conductive boards comprise printed circuit boards (PCBs), wherein each of the PCBs comprises a core board and a metal layer on a surface of the core board.

3. The method according to claim 1, wherein the prepreg layers comprise impregnated resin.

4. The method according to claim 1, wherein a total number of the conductive boards and the prepreg layers in the prepreg substrate is at least ten.

5. The method according to claim 1, wherein the rewiring layer comprises a dielectric layer and a metal wiring layer within the dielectric layer.

6. A chip packaging structure, comprising:
a prepreg substrate, wherein the prepreg substrate comprises two or more layers of conductive boards and prepreg layers, wherein each of the prepreg layers is sandwiched between two of the conductive boards; and
die stacks, disposed on the prepreg substrate, wherein each of the die stacks comprises one of dies and a corresponding segment of a rewiring layer vertically connected to the die.

7. The chip packaging structure according to claim 6, wherein the conductive boards comprise PCBs, wherein each of the PCBs comprises a core board and a metal layer on a surface of the core board.

8. The chip packaging structure according to claim 6, wherein the prepreg layers comprise impregnated resin.

9. The chip packaging structure according to claim 6, wherein a total number of the conductive boards and the prepreg layers in the prepreg substrate is at least ten.

10. The chip packaging structure according to claim 6, wherein the rewiring layer comprises a dielectric layer and a metal wiring layer within the dielectric layer.
